(19) United States
(12) Patent Application Publication
(10) Pub. No.: US 2015/0135853 A1
(43) Pub. Date: May 21, 2015

(54) MEMS PRESSURE SENSOR FIELD SHIELD LAYOUT FOR SURFACE CHARGE IMMUNITY IN OIL FILLED PACKAGING

(71) Applicants: Mark P. McNeal, Northborough, MA (US); Douglas B. Strott, Andover, MA (US); Stephen P. Greene, Scituate, RI (US)

(72) Inventors: Mark P. McNeal, Northborough, MA (US); Douglas B. Strott, Andover, MA (US); Stephen P. Greene, Scituate, RI (US)

(21) Appl. No.: 14/082,562

(22) Filed: Nov. 18, 2013

(51) Int. Cl. G01L 9/08; H01L 41/25; G01F 1/76; G01F 1/34; G01F 1/44

(52) U.S. Cl. CPC G01L 9/08; G01F 1/34; G01F 1/44; G01F 1/76; H01L 41/25
USPC 73/861.351; 73/715; 73/723; 73/861.42; 73/861.63; 29/25.35

(57) ABSTRACT

A pressure sensing element includes a sensing sub-element disposed on a diaphragm, the element including a shield disposed over the sub-element and configured to substantially eliminate influence of external charge on the sub-element during operation. A method of fabrication and a pressure sensor making use of the pressure sensing element are disclosed.

### BACKGROUND OF THE INVENTION

1. Field of the Invention

The invention disclosed herein relates to pressure sensors, and in particular to packaging of a pressure sensor to limit influence of surface charge accumulation in oil filled packages.

2. Description of the Related Art

Offset drift due to surface charge accumulation is a well known phenomenon and common failure mode occurring in a wide variety of semiconductor devices. The failure mechanism involves device surface charge accumulation which drives formation of charge inversion layers. The inversion layers compromise otherwise electrically isolating junction states. Growth of the charge inversion layer permits parasitic current leakage through the epi-layer, resulting in sensing element offset drift. As with many other types of devices, pressure sensing elements are influenced by this phenomenon.

Present day designs for pressure sensing elements that include a field shield are susceptible to surface charge accumulation and exhibit severe offset drift due to sense element charging. This is especially the case when deployed in oil encapsulated package assemblies and applications.

In many package configurations, the pressure sensing element is encapsulated by a dielectric oil. The oil provides for coupling of external absolute or differential pressure inputs with the sense element. Unfortunately, this also serves to couple external, electrostatic charge residing on the package, or elsewhere, to the sensing surface of the pressure sensing element. Typically, charge coupling occurs through polar alignment of molecules in the oil in response to an external field, and associated space charge accumulation at an interface of the sense element and the oil. Consequently, comparatively large external static charge may be coupled to the sensing element via the molecular polarizability of the oil. Such charge may be residing on, for example, plastic housing assemblies used to package the sensing element or introduced to the housing by electrostatic discharge (ESD) to the plastic package. This high static charge is more than sufficient to cause severe output shift.

Thus, what are needed are methods and apparatus to improve the performance of pressure sensors encapsulated in an oil containing package.

### SUMMARY OF THE INVENTION

In one embodiment, a pressure sensing element is provided. The pressure sensing element includes a sensing sub-element disposed on a diaphragm, the element including a shield disposed over the sub-element and configured to substantially eliminate influence of external charge on the sub-element during operation.

In another embodiment, the method for fabricating a pressure sensing element is provided. The method includes selecting a pressure sensing element including a sub-element disposed on a diaphragm; and disposing a shield over the sub-element and configuring the shield to substantially eliminate influence of external charge on the sub-element during operation.

In a further embodiment, a pressure sensor is disclosed. The pressure sensor includes a pressure sensing element including a sensing sub-element disposed on a diaphragm, the element including a shield disposed over the sub-element and configured to substantially eliminate influence of external charge on the sub-element during operation; and a port for exposing the pressure sensing element to a pressure environment. At least another pressure sensing element may be included.

### BRIEF DESCRIPTION OF THE DRAWINGS

The features and advantages of the invention are apparent from the following description taken in conjunction with the accompanying drawings in which:

FIG. 1 is an isometric diagram depicting aspects of an exemplary pressure sensing element according to the teachings herein;

FIG. 2 is an isometric diagram depicting aspects of a pedestal for the pressure sensing element of FIG. 1;

FIGS. 3 and 4 are isometric diagrams depicting aspects of a silicon die for the pressure sensing element of FIG. 1;

FIG. 5 is a cutaway isometric diagram of the pressure sensing element of FIG. 1;

FIG. 6 is a top down view of the pressure sensing element of FIG. 1;

FIG. 7 is an isometric view of a pressure sensor that includes pressure sensing elements as shown in FIG. 1;

FIG. 8 is a cutaway view of the pressure sensor depicted in FIG. 7;

FIG. 9 is a schematic view depicting an application of the pressure sensor depicted in FIG. 7; and

FIG. 10 is a graph depicting comparative performance of sensing elements.

### DETAILED DESCRIPTION OF THE INVENTION

Disclosed herein are methods and apparatus for limiting the influence of surface charge or large static charge accumulation that may cause signal offset in a pressure sensor. Sources of the extraneous charge may include packaging of the sensing element. Advantageously, this generally results in immunity against drift in output data from the sensor.

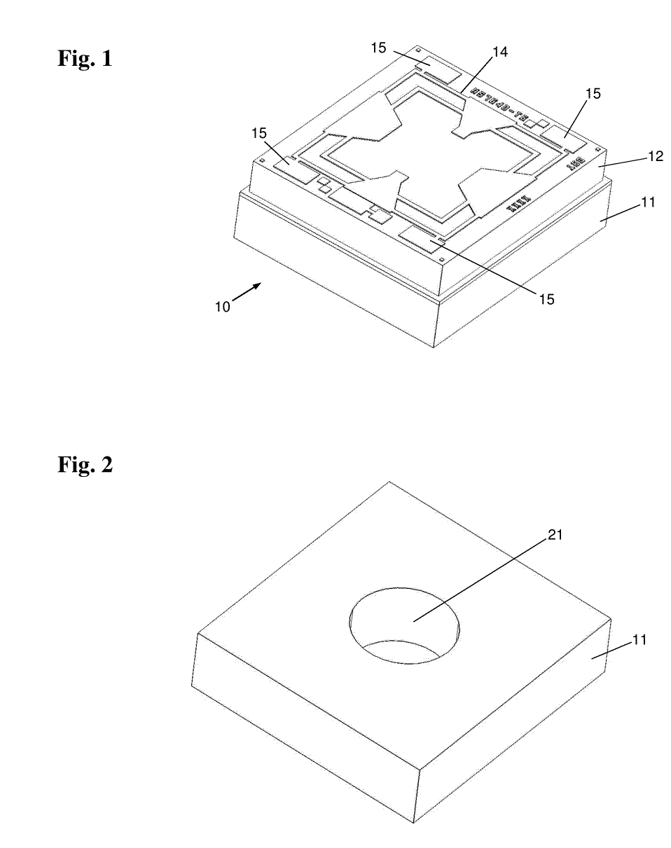

Referring now to FIG. 1, there is shown a pressure sensing element 10 according to the teachings herein. In this embodiment, the pressure sensing element 10 includes a pedestal 11 as a base to the pressure sensing element 10. The pedestal 11 may be formed of a suitable material such as glass. Disposed on top of the pedestal 11 is a silicon die 12. The silicon die 12 may be bonded to the pedestal 11 using techniques as are known in the art. The silicon die 12 is host to a metal layout 14. Included in the metal layout 14 are a plurality of bond pads 15. The bond pads 15 provide for electrical connection of the pressure sensing element 10 with external components. Generally, the external components provide for powering and receiving data from the pressure sensing element 10 and processing the data.

Referring to FIG. 2, a perspective view of an embodiment of the pedestal 11 is shown. In this example, other components of the pressure sensing element 10 have been omitted such that features of the pedestal 11 may be better presented. In this example, the pedestal 11 includes a central thruway 21 that provides a pressure port for sampling pressure. Accordingly, the thruway 21 is also referred to herein as a “port” 21. Generally, one side of the pedestal 11 is exposed to a sampling environment for sampling of pressure therein. An opposing side of the pedestal 11 is exposed to internals of the pressure sensing element 10. Accordingly, liquids and/or gases in the sampling environment will flow into the pressure sensing element 10 through the port 21. The port 21 may be provided in a variety of forms. For example, it is not necessary that the thruway 21 be provided as a singular, cylindrical penetration through a center of the pedestal 11 as shown. In one embodiment, the thruway 21 includes a plurality of smaller perforations through a thickness of the pedestal 11. In a final embodiment (not shown), the central thruway 21 may terminate at some depth in the glass, forming a cavity. In this embodiment, the cavity may be evacuated or backfilled to fixed reference pressure, configuring sensing element 10 for absolute pressing sensing.

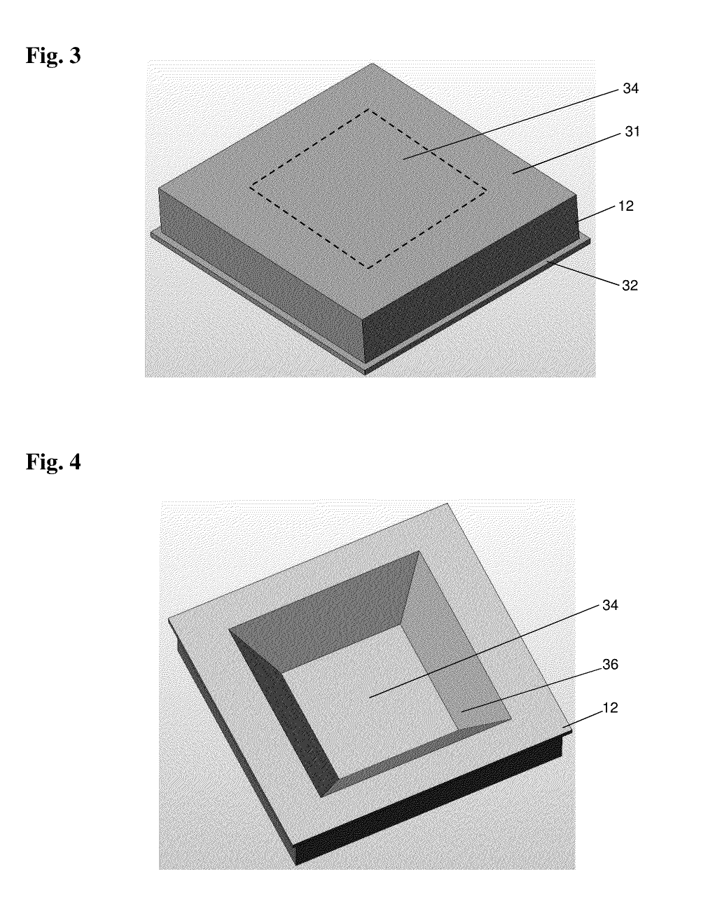

Referring now to FIG. 3, a perspective view of an embodiment of the silicon die 12 is shown. In this example, other components of the pressure sensing element 10 have been omitted such that features of the silicon die 12 may be better presented. In this example, the silicon die 12 includes an optional flange 32. The flange 32 may be useful for assembly of the pressure sensing element 10. For example, during assembly, mechanical pressure may be applied to the flange 32 such that an underlying adhesive is evenly distributed and compressed onto the pedestal 11. The silicon die 12 includes a top 31. Generally, the top 31 includes a substantially planar surface. Within a central portion of the top 31 is a diaphragm 34. Generally, the diaphragm 34 will bulge upwardly or flex according to pressure experienced by the pressure sensing element 10.

Referring now to FIG. 4, a perspective view of an underside of the silicon die 12 is shown. In this example, the silicon die 12 includes a cavity 36. When the silicon die 12 is mated with the pedestal 11, the cavity 36 results in a chamber for receiving a sampling environment. Generally, the cavity 36 is defined by a wall (such as where the cavity 36 is cylindrical in form), or a plurality of walls (as shown in FIG. 4). The diaphragm 34 is defined by a base of the cavity 36, and may be of a substantially uniform thickness.

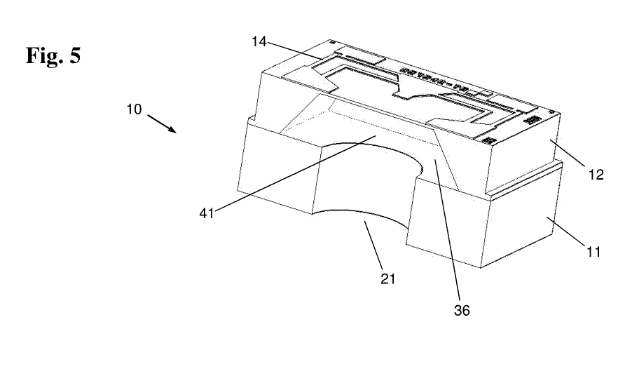

Referring now to FIG. 5, a semi-transparent perspective view of the pressure sensing element 10 is shown. In this illustration, it may be seen that the cavity 36 of the silicon die 12 forms a chamber 41 when the silicon die 12 is mated with or joined to the pedestal 11.

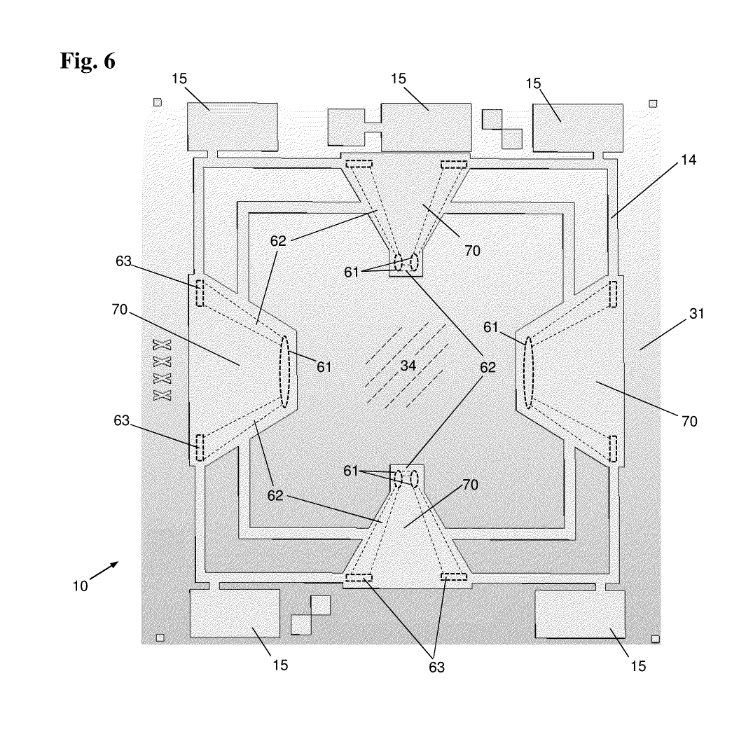

Referring now to FIG. 6, a top-down view of an exemplary embodiment of the pressure sensing element 10 is shown. In this example, the metal layout 14 is shown in greater detail. Included in the metal layout 14 is a plurality of sensing sub-elements 61. The sensing sub-elements 61 may include any type of component that provides for measuring a deflection or distortion of the diaphragm 34. For example, the sensing sub-elements 61 may include piezoresistive elements formed by light, positively doped (P⁻) silicon. The sensing sub-elements 61 are electrically coupled to respective electrical contact vias 63 by respective highly positively doped (P⁺) solid-state interconnects 62. The electrical contact vias 63 and interconnects 62 may be fabricated from semiconductor materials such as positively doped semiconductor materials. The metal layout 14 may be disposed onto the top 31 of the silicon die 12 through techniques such as photolithography, by deposition, or by other techniques deemed appropriate. The electrical contact vias 63 and interconnects may be implanted in the material of the silicon die 12, with the metal layout 14 disposed there over. A respective field shield 70 is disposed over the sensing sub-elements 61, the electrical contact vias 63, and the interconnects 62. The respective field shield 70 is disposed over and electrically insulated from sub-elements 61, the electrical contact vias 63, and the interconnects 62, by a thin passivation film of suitable material, typically vapor deposited Si₃N₄ and/or thermally grown SiO₂.

As shown in this illustration, the pressure sensing element 10 includes four respective circuit devices (i.e., four separate groupings of sensing sub-elements 61, electrical contact vias 63, and the interconnects 62). It should be understood that the pressure sensing element 10 may include additional or fewer groupings, and that grouping selected may be arranged in any manner determined appropriate to provide a desired function. Further, it should be understood that the circuit devices may be of any geometry (for example, shape, profile, width, thickness and the like) deemed appropriate.

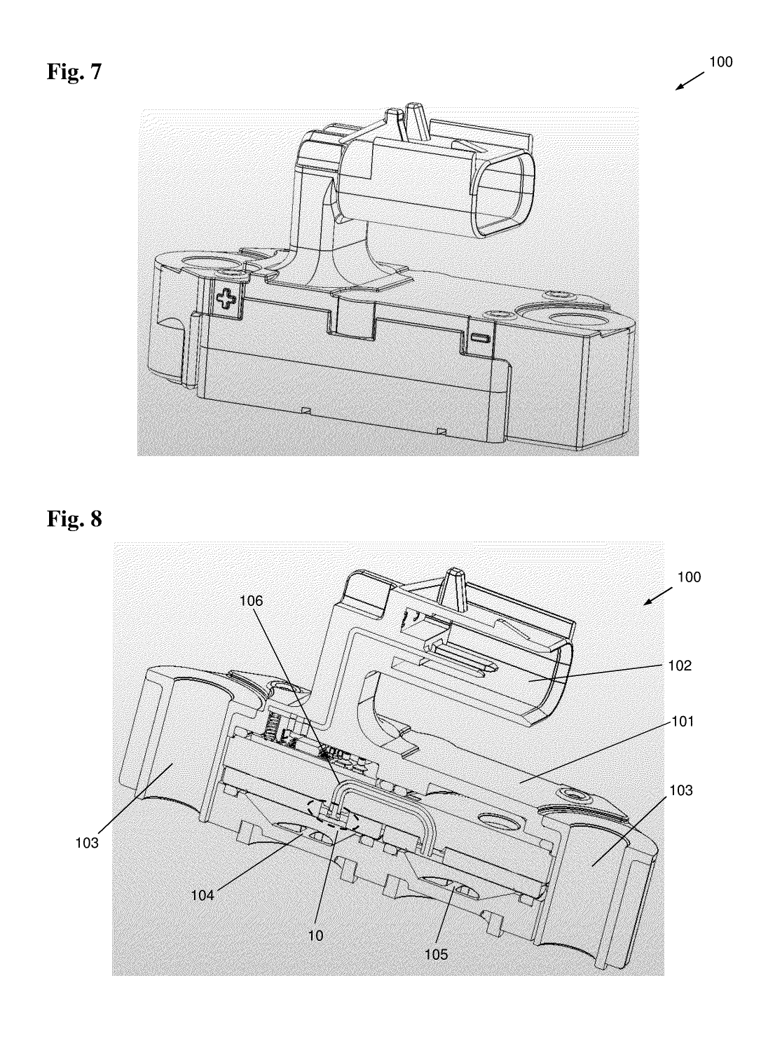

Referring now to FIG. 7, there is shown an exemplary pressure sensor 100. The pressure sensor 100 makes use of pressure sensing element 10 as disclosed herein.

FIG. 8 is a cutaway view of the illustration of FIG. 7. The exemplary pressure sensor 100 includes a body 101. The body 101 includes a port 102. Generally, the port 102 houses connectors for providing external connection to electrical systems. The body 101 includes at least one mount 103. The at least one mount 103 is useful for securing the pressure sensor 100 in place. In this example, the pressure sensor 100 includes a high-pressure port 104 and a low-pressure port 105. Pressure is communicated between the high-pressure port 104 and the low-pressure port 105 by a tube 106. Generally, the tube 106 is filled with oil. Disposed at the high-pressure end of the tube 106 is a respective pressure sensing element 10.

The tube 106 may be considered as an embodiment of a reservoir of oil. The reservoir provides for coupling pressure port 21 of a pressure sensing element 10 to the low-pressure port 105. In this example, the reservoir of oil is provided in an extended tube or column. However, the reservoir may be of any geometry deemed appropriate for coupling environmental pressure to sensing element 10. For absolute pressure configuration port 21 forms reference cavity, with pressure coupled to sensing element top side 31. For relative or differential pressure sensing, the reservoir provides pressure coupling to central thruway 21, with at least another pressure port coupled to the opposing side of sensing element 10 as appropriate for determining differential pressure (i.e., pressurewise coupling). A high-pressure port 104 couples high pressure to the sensing element 10 top side diaphragm 34 for the configuration described in this disclosure.

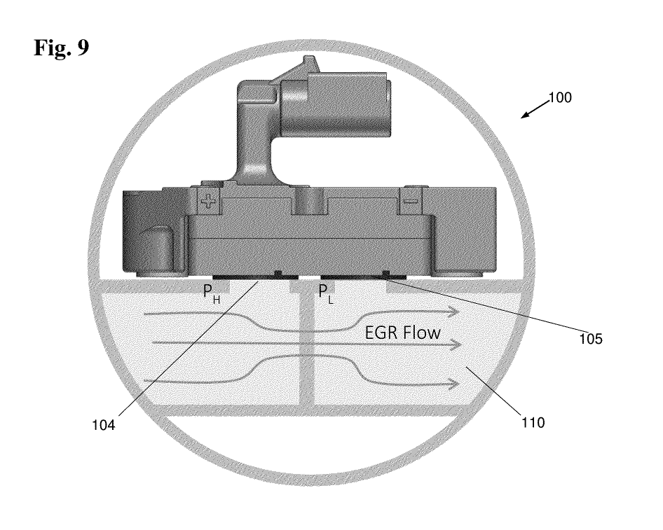

Referring now also to FIG. 9 where an embodiment of the exemplary pressure sensor 100 is shown installed. In this example, the pressure sensor 100 is installed on a pressurized environment 110. The pressurized environment 110 includes a flow (in this illustration, from left to right). An exemplary pressurized environment 110 includes exhaust gas recirculation flow. By enabling measurement of pressure in the high-pressure port 104 as well as pressure in the low-pressure port 105, a system making use of the pressure sensor 100 may be configured for making assessments of common pressure, differential pressure, flow dynamics and other related quantities.

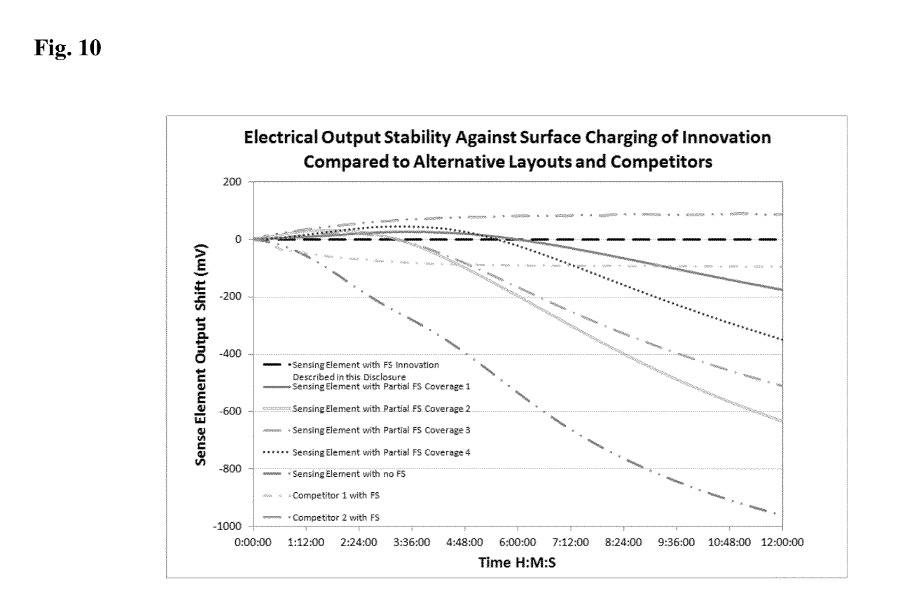

FIG. 10 provides a graphical depiction of embodiments of pressure sensors. In embodiment designed according to the teachings presented herein did not exhibit any drift at all. In contrast drift for prior art designs ranged from moderate to substantial.

More specifically, and by way of non-limiting example, measurement of pressure drop across a Venturi flow tube enables calculation of mass airflow. In some embodiments, pressure differential that may be measured ranges from about 0.2 bar to about 1 bar. Common mode measurement of pressure range as high as about 8 bar.

Some additional aspects of the pressure sensing element 10 are now introduced.

Generally, each field shield may be extended to fully cover each implanted device circuit, contact vias and areas of the metal interconnects, as necessary to prevent formation of low resistance inversion channel between P+ interconnects. Typical prior art designs limit field shield coverage on the sensing element to the piezoresistive bridge and portions of the highly doped P+ interconnects, whereby uncovered implanted areas remain susceptible to charging and formation of inversion layer. Accordingly, design of the circuit devices may be modified to accommodate the piezoresistive elements, and to fully cover P+ doped interconnects, electrical contact vias, and metal interconnects, as needed for complete immunity against surface charging.

Specific to this innovation, the field shield metal, layout and method of deposition provide low membrane stress coupling for superior device performance of low pressure (less than about 1 Bar) die. The metal may be of any type common to the industry, including elemental, alloys or compound mixture. In practice, the field shield is isolated from the first metal layer by an intervening layer of passivation, for instance, silicon nitride, with contact vias to the epitaxial layer. The orientation and layout of sensing sub-elements, contact vias, and interconnects are such that area of metal coverage on diaphragm is minimized. Minimizing metal coverage insures minimum stress coupling from the metal field shield to sensing element diaphragm of low pressure die. Depositing films sufficiently thin insures maximum device sensitivity. Metal film thickness used in this innovation is generally about 100 nm to about 50 nm or less. Thicker metals may be used as well. The field shield arrangement described herein may also be deployed on sensing elements of any pressure range (greater than about 1 Bar) die. In particular, completely covering the diaphragm of a low pressure die with a thick metal or other material degrades performance. Thicker films shift the neutral stress axis away from the piezoresitive elements, therefore lowering sensitivity; and introduce higher mechanical stress coupling to the membrane, therefore impacting accuracy and over-life stability. In operation, an equivalent potential is applied to both field shield layer and epitaxial substrate layer, generally bridge voltage, V_{b}, to maintain a neutral field between the field shield metal and epitaxial substrate for environmental conditions that may be encountered during normal operation. The maintenance of the neutral field across all active areas, even with very high accumulation of surface charge, ensures long term output stability of the device. Bench tests used to induce sense element charging and output drift confirm superior performance of the techniques disclosed herein.

As discussed herein, terminology relating to “electrical separation” generally refers to conditions adequate for maintaining a neutral field between electrical components. In some embodiments, electrical separation may also be referred to as electrical isolation. Electrical separation may be realized by application of intervening layers such as a passivation layer. In some embodiments, electrical separation may rely upon (or additionally make use of) biasing of a circuit element.

As discussed herein, “substantially eliminating influence of external charge on the sensing element” generally refers to reducing influence of charge accumulation on output of the sensing element. For example, substantially eliminating influence of external charge results in reductions of output drift to levels that are within acceptability for a particular design, or from the perspective of a designer, manufacturer, user, or other similarly interested person. Alternatively, substantially eliminating influence of external charge results in reductions of output drift to levels that exceed the performance of competitive designs.

Various other components may be included and called upon for providing for aspects of the teachings herein. For example, additional materials, combinations of materials and/or omission of materials may be used to provide for added embodiments that are within the scope of the teachings herein.

When introducing elements of the present invention or the embodiment(s) thereof, the articles “a,” “an,” and “the” are intended to mean that there are one or more of the elements. Similarly, the adjective “another,” when used to introduce an element, is intended to mean one or more elements. The terms “including” and “having” are intended to be inclusive such that there may be additional elements other than the listed elements.

While the invention has been described with reference to exemplary embodiments, it will be understood by those skilled in the art that various changes may be made and equivalents may be substituted for elements thereof without departing from the scope of the invention. In addition, many modifications will be appreciated by those skilled in the art to adapt a particular instrument, situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A pressure sensing element comprising a sensing sub-element disposed on a diaphragm, the element comprising:
a field shield disposed over the sub-element, a contact via and an interconnect disposed between the sub-element and the contact via, the field shield configured to substantially eliminate influence of external charge on the sub-element during operation.

2. The sensing element of claim 1, wherein the sub-element comprises at least one piezoresistive element.

3. The sensing element of claim 1, wherein the sub-element is implanted into the diaphragm.

4. The sensing element of claim 1, wherein a layer is disposed between the field shield and the sub-element.

5. The sensing element of claim 4, wherein the layer comprises a passivation layer.

6. The sensing element of claim 1, wherein the field shield is configurable to substantially eliminate influence of external charge on the sensing element.

7. The sensing element of claim 1, wherein the field shield is disposed over the sub-element by one of photolithography and deposition.

8. The sensing element of claim 1, wherein sources of the external charge comprise at least one of oil in which the sensing element is at least partially immersed and other components surrounding the sensing element.

9. A method for fabricating a pressure sensing element, the method comprising:
selecting a pressure sensing element comprising a sub-element disposed on a diaphragm; and
disposing a field shield over the sub-element, a contact via and an interconnect disposed between the sub-element and the contact via, the field shield configuring the field shield to substantially eliminate influence of external charge on the sub-element during operation.

10. The method as in claim 9, further comprising disposing a layer between the field shield and the sub-element.

11. The method as in claim 9, wherein the configuring comprises covering the interconnect, the contact via and the sub-element with a metallic composition to limit the influence of the external charge.

12. A pressure sensor comprising:
a pressure sensing element comprising a sensing sub-element disposed on a diaphragm, the element comprising a shield disposed over the sub-element, a contact via and an interconnect disposed between the sub-element and the contact via, the field shield configured to substantially eliminate influence of external charge on the sub-element during operation; and
a port for exposing the pressure sensing element to a pressure environment.

13. The pressure sensor as in claim 12, comprising another port and another pressure sensing element.

14. The pressure sensor as in claim 13, wherein a top side of the diaphragm and a back side of the port are coupled by a reservoir of oil.

15. The pressure sensor as in claim 13, wherein measurements of differential pressure span a range of between about 0.2 bar and 1 bar.

16. The pressure sensor as in claim 13 configured for measuring differential pressure across a Venturi flow tube.

17. The pressure sensor as in claim 13 configured for measuring mass air flow.
